(19) United States
(12) Patent Application Publication
(10) Pub. No.: US 2017/0085078 A1
(43) Pub. Date: Mar. 23, 2017

(54) HOT PLUG IMMUNITY FOR CIRCUIT PROTECTING AGAINST ELECTROSTATIC DISCHARGE EVENTS

(71) Applicant: Texas Instruments Incorporated, Dallas, TX (US)

(72) Inventor: Farzan Farbiz, Dallas, TX (US)

(21) Appl. No.: 14/858,709

(22) Filed: Sep. 18, 2015

(51) Int. Cl. H02H 9/04; H01L 27/02

(52) U.S. Cl. CPC H02H 9/046; H01L 27/0274

(57) ABSTRACT

A hot plug immune circuitry (100) for protecting against electrostatic discharge events comprises an input/output (I/O) pad (101) of an electronic system with a pad threshold voltage and connections to ground potential by a first circuit (110) and a parallel second circuit (130). The first circuit includes a MOS field-effect transistor (FET) (111) doubling as a parasitic bipolar transistor. The second circuit is a voltage level sensor formed as a voltage divider with a first impedance (131) tied by a link (133) in series with a second impedance (132). Link (133) is cross-tied (134) to the FET of the first circuit, and carries a shut-off voltage for the FET determined by the pad threshold voltage diminished by the ratio of the first and the second impedances.

### FIELD OF THE INVENTION

Embodiments of the invention are related in general to the field of semiconductor devices and processes, and more specifically to the structure and fabrication method of electrostatic discharge circuits having hot plug immunity.

### DESCRIPTION OF RELATED ART

Integrated circuits (ICs) may be severely damaged by electrostatic discharge (ESD) events. A major source of ESD exposure to ICs is from the human body (described by the “Human Body Model”, HBM); the discharge of the human body generates peak currents of several amperes to the IC for about 100 ns. A second source of ESD is from metallic objects (described by the “Machine model”, MM); it can generate transients with significantly higher rise times and current levels than the HBM ESD source. A third source is described by the “charged device model” (CDM), in which the IC itself becomes charged and discharges to ground in rise times less than 500 ps.

ESD phenomena in ICs are growing in importance as the demand for higher operating speed, smaller operating voltages, higher packing density and reduced cost drives a reduction of all device dimensions. This generally implies thinner dielectric layers, higher doping levels with more abrupt doping transitions, and higher electric fields—all factors that contribute to an increased sensitivity to damaging ESD events.

One common scheme to protect an input/output (I/O) pad against ESD failure uses metal-oxide-semiconductor (MOS) ICs, such as nMOS field-effect transistor (FET) with its drain connected to the pin to be protected and its source tied to ground, and relies on the mode of a parasitic bipolar transistor (the source acts as the emitter, the drain as the collector, and the bulk semiconductor as the base) during an ESD event to provide a low impedance current path to ground; the parasitic bipolar transistor operates in the snapback region (the bipolar turn-on at snapback occurs at the collector/drain voltage Vₜ₁ with an associated collector/drain current Iₜ₁) under pin positive with respect to ground stress events. The dominant failure mechanism is the onset of second breakdown. The protection level or failure threshold can be set by varying the nMOS device width.

The current carrying capability of the device is limited by thermal effects in the avalanching collector depletion layer. A number of effects (such as the increase of intrinsic carrier concentration, a reduction of carrier mobility, a decrease in thermal conductivity, and a lowering of the potential barrier for tunnel currents) contribute to the onset of thermal runaway, the second (thermal) breakdown. The reduction of the impact ionization current is offset by the thermal generation of carriers. Second breakdown, initiated in a device under stress as a result of self-heating, is characterized by the trigger current Iₜ₂, which is very sensitive to the device design, especially the doping profiles; it results in junction melting and in an irreversible increase in leakage currents.

Another common protection scheme used in MOS ICs employs a first diode with its cathode connected to the power (V_{DD}) terminal for positive ESD stress and its anode connected to the I/O pad to be protected. The diode has to be made of large area, since the on-resistance of the diode determines the effectiveness. A second diode has its anode connected to ground potential (V_{SS}) for negative ESD stress and its cathode to the pad.

A variant of this scheme still uses the first diode for positive ESD stress, but employs a MOS FET in place of the second diode, with the drain of a MOS transistor tied to the pad and the source tied to ground potential; the gate is typically also connected to ground through a resistor. For negative ESD stress, the parasitic diode of the transistor, formed by the pad as cathode and V_{SS} as anode, offers protection. In many devices, the semiconductor substrate is p-type so that the diode is built in an n-well as a pn diode and the transistor is an nMOS transistor. The parasitic bipolar pnp transistor of the diode pumps current into the substrate of the transistor, triggering it as an effective npn device. The efficiency of this protection depends on the capacitance associated with the V_{DD} terminal; if it were too small, the vertical pnp shuts off before the HBM event, causing premature failure in the MOS transistor.

Yet another known ESD protection scheme applies to semiconductor devices integrating RF, analog and digital circuits on the same substrate using a so-called fail-safe design, which do not allow a diode between the I/O pad and V_{DD}. In these ESD protection devices, the I/O pad is connected to the anode of a forward biased diode located in a well with conductivity opposite to the substrate conductivity. The diode cathode is tied to the drain of an MOS transistor formed in the substrate; source and gate of the MOS transistor are connected to ground potential, V_{SS}. The MOS transistor forms a parasitic bipolar npn transistor with the collector at the drain, the emitter at the source, and the base at the resistive substrate. The protection concept is sometimes referred to as diode-isolated MOS FET concept.

The ESD trigger current Iₜ₂ in the diode-isolated MOS protections has typically two components, which follow different routes from the pad to ground: One current path is through the forward biased diode and the parasitic npn transistor, and the other current path through a parasitic silicon-controlled rectifier (SCR) formed by the diode anode as SCR anode, the well, the substrate, and the source of the MOS transistor as the SCR cathode. The SCR is thus formed by the vertical pnp from the n-well diode with the lateral npn of the nMOS transistor. As mentioned above, in order to achieve low diode on-resistance and sufficient substrate pumping to turn on the MOS transistor, the diode has to have a large area.

In the current-voltage characteristic of the SCR, the SCR trigger voltage V_{trig} is set by the reverse junction breakdown of the drain of the MOS transistor; V_{trig} must be higher than the maximum desired pin application of the I/O. The SCR holding voltage V_{hold} is set by the spacing between the anode of the diode and the source of the MOS transistor. A low V_{hold} allows for robust ESD protection and power dissipation.

During normal device operation, ESD circuits for protecting a device pin are expected to be off. However, when an ESD circuit is activated by sensing a fast-rising voltage ramp at the pin even when the rise is not caused by an ESD event but rather the on-going operation of the device (so-called hot plug event), current will be allowed to flow much longer time through the circuit than in an ESD event. Consequently, the energy dissipated by voltage, current and time is likely to surpass the design limit of the protection circuit, causing uncontrolled temperature rise and destruction of the protection circuit.

One method of existing technology to prevent such failure employs a design of the active FET to conduct an ESD current with less than half V_{DD} voltage drop. The maximum ESD current is between the current at V=V_{DD}/2 and the current at V_{DD}.

Another method of existing technology employs snap-back devices; this method renders the protection circuit immune to hot-plug events for trigger voltages V_{trig}>V_{DD}_{_}ₘₐₓ.

### SUMMARY

The marketplace for electronic systems such as computers, machine controls, operation controls, and other systems requires ever more frequently the capability for users to perform operations such as component replacements, repairs, and additions without shutting down or interrupting the system. It has been experienced that ESD protection circuits often interpret these hot plug operations erroneously as an incoming ESD events, with the fatal consequence that the protection circuits burn out due to catastrophic overheating.

Applicant realized that available preventive techniques, such as employing snap-back devices in electronic systems, may require expensive development for creating new components, or may not easily be amenable to simulations in SPICE and other design systems, or may have latch-up concerns when conditions are not optimal (when for instance the holding voltage is less than the supply voltage).

Applicant solved the problem of forming a circuit with an FET to ground potential, which protects a pad against ESD events but is immune against hot plug operations, when he discovered a methodology of adding a shut-off pin to the circuit, which is able to sense an incoming fast-rising voltage ramp, to interpret the rise correctly as a hot-plug event and not an ESD event, and then to shut off the FET of the protection circuit from the pad.

A preferred method of coupling the shut-off pin with the protection circuit includes a divider having linear elements, such as the impedance of resistors, capacitors, and inductors. The first impedance of the divider is tied to the pad-to-be-protected and the second impedance to ground potential. The ratio of the impedances is selected by the voltage deemed necessary on the shut-off pin to turn off the FET of the protection circuit from the pad. When the impedance is a resistor or a capacitor, it may be selected as a programmable resistor or capacitor so that the threshold of the voltage sensing circuit can be adjusted.

Another method of connecting the shut-off pin with the protection circuit includes a divider having at least one non-linear element such as a diode characterized by breakdown, like a Zener diode. The non-linear element of the divider is tied to the pad-to-be-protected, the linear element such as a resistor is tied to ground potential. The voltage at the enable pin needed to turn off the ESD protection circuit is the difference between the voltage at the pad and the breakdown voltage of the selected Zener diode.

### BRIEF DESCRIPTION OF THE DRAWINGS

FIG. 1 illustrates a diagram of a hot immune circuit for protecting an input/output (I/O) pad against electrostatic discharge events.

FIG. 2 depicts a diagram of another hot immune circuit for protecting an input/output (I/O) pad against electrostatic discharge events.

FIG. 3A shows the voltage-time characteristic of a pulse at a pad tied to a hot plug immune circuit protecting against electrostatic discharge events according to the invention.

FIG. 3B illustrates the current-time characteristic corresponding to the voltage-time characteristic of FIG. 3A at a pad tied to a hot plug immune circuit protecting against electrostatic discharge events according to the invention.

FIG. 4A shows the voltage-time characteristic of a pulse at a pad tied to a circuit protecting against electrostatic discharge events according to conventional technology.

FIG. 4B illustrates the current-time characteristic corresponding to the voltage-time characteristic of FIG. 4A at a pad tied to a circuit protecting against electrostatic discharge events according to conventional technology.

FIG. 5 displays a diagram of another hot immune circuit for protecting an input/output (I/O) pad against electrostatic discharge events.

FIG. 6 shows a diagram of a process flow for fabricating a hot plug immune circuit protecting against electrostatic discharge events.

FIG. 7 shows a diagram of another process flow for fabricating a hot plug immune circuit protecting against electrostatic discharge events.

### DETAILED DESCRIPTION OF THE PREFERRED EMBODIMENTS

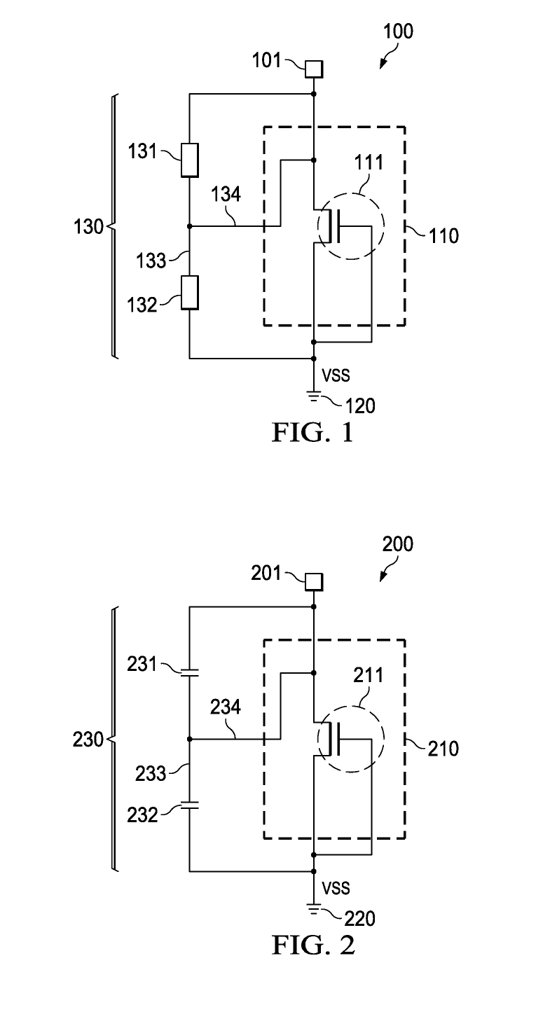

FIG. 1 illustrates an exemplary embodiment of the invention to create a hot plug immune circuit, generally designated 100, for protecting a pad 101 against electrostatic discharge events. Pad 101 has a pad threshold voltage V_{pad}_{_}ₜₕ. The protection circuit, designated 110, includes a MOS field effect transistor (FET) 111, which has its drain connected to pad 101 and its source, together with its gate, tied to ground potential V_{SS} 120. For protection, circuit 110 relies on the mode of a parasitic bipolar transistor (the source acts as the emitter, the drain as the collector, and the bulk semiconductor as the base) during an ESD event to provide a low impedance current path to ground; the parasitic bipolar transistor operates in the snapback region (the bipolar turn-on at snapback occurs at the collector/drain voltage Vₜ₁ with an associated collector/drain current Iₜ₁).

Pad 101 is further connected to ground potential by a voltage divider, which aligns a first electronic element in series with a second electronic element. As an example, FIG. 1 illustrates the divider as an impedance divider 130, which aligns a first linear electronic impedance Z₁ (131) in series with a second linear electronic impedance Z₂ (132). The first linear impedance Z₁ is coupled to pad 101 and the second linear impedance Z₂ is coupled to ground potential 120. The link 133 between the impedances is connected by cross-tie p₀ (134) to the FET 111 of the protection circuit. Cross-tie 134 is operable to shut off FET 111 from pad 101 at a shut-off threshold voltage Vₚ₀_{_}ₜₕ. Cross-tie 134 if frequently referred to as shut-off pin. In other words, voltage Vₚ₀_{_}ₜₕ indicates how much voltage is needed at the shut-off pin 134 to turn off protection circuit 110.

Between the impedance divider 130 and the protection circuit 110 holds the following relationship:

Z₂/Z₁=(V_{pad}_{_}ₜₕ−Vₚ₀_{_}ₜₕ)/Vₚ₀_{_}ₜₕ;

or re-written: Z₂/Z₁=(V_{pad}_{_}ₜₕ/Vₚ₀_{_}ₜₕ)−1.

The voltage available at the shut-off pin 134 to turn off protection circuit 110 is

$$\begin{matrix}{V}_{p 0\_ th} = {V}_{pad\_th} / ( {Z}_{2} / {Z}_{1} + 1 ) \\ = {V}_{pad\_th} {Z}_{1} / ( {Z}_{1} + {Z}_{2} ) .\end{matrix}$$

The shut-off voltage at shut-off pin 134 is thus controlled by the pad terminal voltage diminished by the ratio of the second and first linear impedance, or more generally, by the ratio of the second and first electronic elements in series.

Having added the voltage divider by the series of linear impedances Z₁ and Z₂ and thus having connected the shut-off pin 134 by an impedance divider to pad 101, the shut-off pin is able to sense an incoming fast-rising voltage ramp as the rapidly and continuously increasing voltage spike of a hot plug event rather than of an ESD event. Shut-off pin 134 is then able to shut off the FET of the protection circuit from the pad and thus avoid overheating and destruction of circuit 110.

The linear impedances Z may include resistors, capacitances, inductors, and combinations thereof. The resistors and capacitances do not have to have fixed values but may be programmable so that the threshold of the voltage sensing circuit can be adjusted. Selecting capacitors, the voltage divider of FIG. 1 is morphing into the capacitor divider of FIG. 2. Pad 201, which needs to be protected by hot plug immune circuitry 200 against ESD events, has a pad threshold voltage V_{pad}_{_}ₜₕ. The protection circuit, designated 210, includes a MOS field effect transistor (FET) 211, which has its drain connected to pad 201 and its source, together with its gate, tied to ground potential V_{SS} 220. For protection, circuit 210 relies on the mode of a parasitic bipolar transistor (the source acts as the emitter, the drain as the collector, and the bulk semiconductor as the base) during an ESD event to provide a low impedance current path to ground; the parasitic bipolar transistor operates in the snapback regime.

Pad 201 is further connected to ground potential by a capacitor divider 230, which aligns a first capacitor 231 in series with a second capacitor 232. The first capacitor 231 (C₁) is coupled to pad 201 and the second capacitor 232 (C₂) is coupled to ground potential 220. The link 233 between the capacitors is connected by cross-tie p₀ (234) to the FET 211 of the protection circuit. Cross-tie 234 is operable to shut off FET 211 from pad 201 at a shut-off threshold voltage Vₚ₀_{_}ₜₕ:

$$\begin{matrix}{V}_{p 0\_ th} = {V}_{pad\_th} / ( {C}_{2} / {C}_{1} + 1 ) \\ = {V}_{pad\_th} {C}_{1} / ( {C}_{1} + {C}_{2} ) .\end{matrix}$$

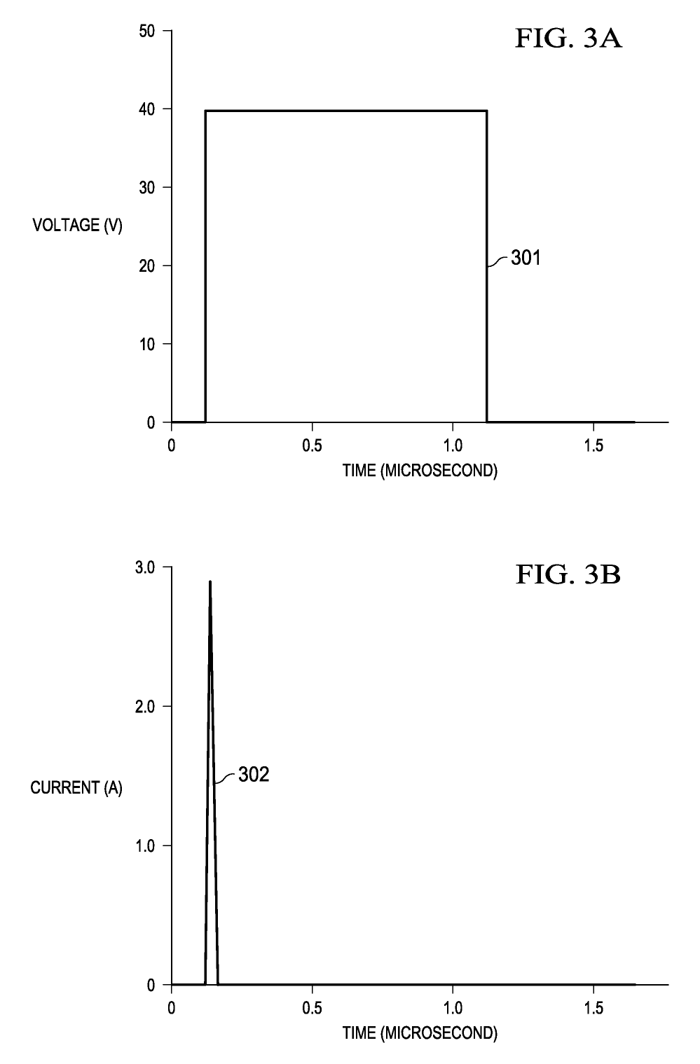

The success of shut-off pin 134 is illustrated by the numerical example of FIGS. 3A and 3B. In this example, the pad is selected for 40 V. The shut-off pin is activated by a voltage-level-sensing capacitor divider designed so that the ESD protection circuit 210 is enabled as long as the voltage Vₚ₀_{_}ₜₕ at the pin remains under 10 V. However, an increase of Vₚ₀_{_}ₜₕ over 10 V should activate the shut-off pin and disable the protection circuit. With this voltage-level-sensing characteristic, a hot plug event can be distinguished from an ESD event.

In FIG. 3A, the voltage (in V) at the shut-off pin is plotted as a function of time (μs). As curve 301 shows, the voltage stays at 40 V for about 1 μs. In FIG. 3B, the corresponding current (in A) at the shut-off pin is plotted on the same time scale (μs). As curve 302 shows, the current spikes at about 3 A after a time lapse of only 0.02 μs, before the shut-off pin disables protection circuit 210. Consequently, the energy which the incoming pulse is permitted to dissipate is very small (about 40 A·3 V·2·10⁻⁸ s=2.4·10⁻⁶ J).

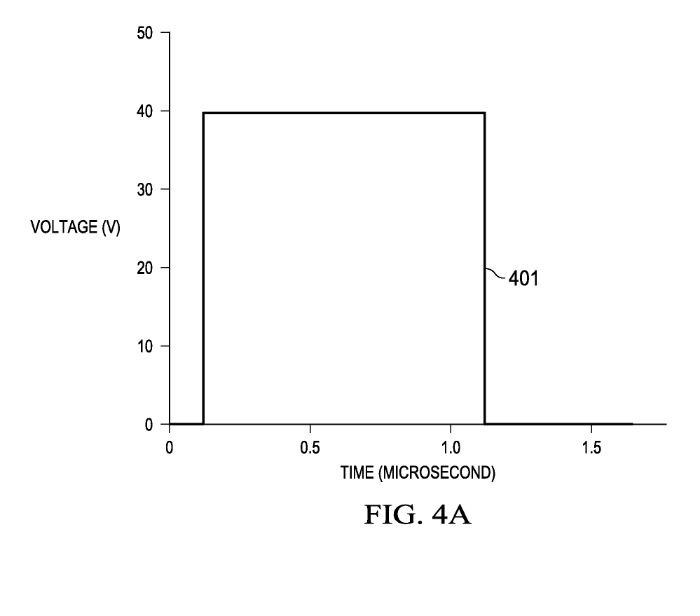

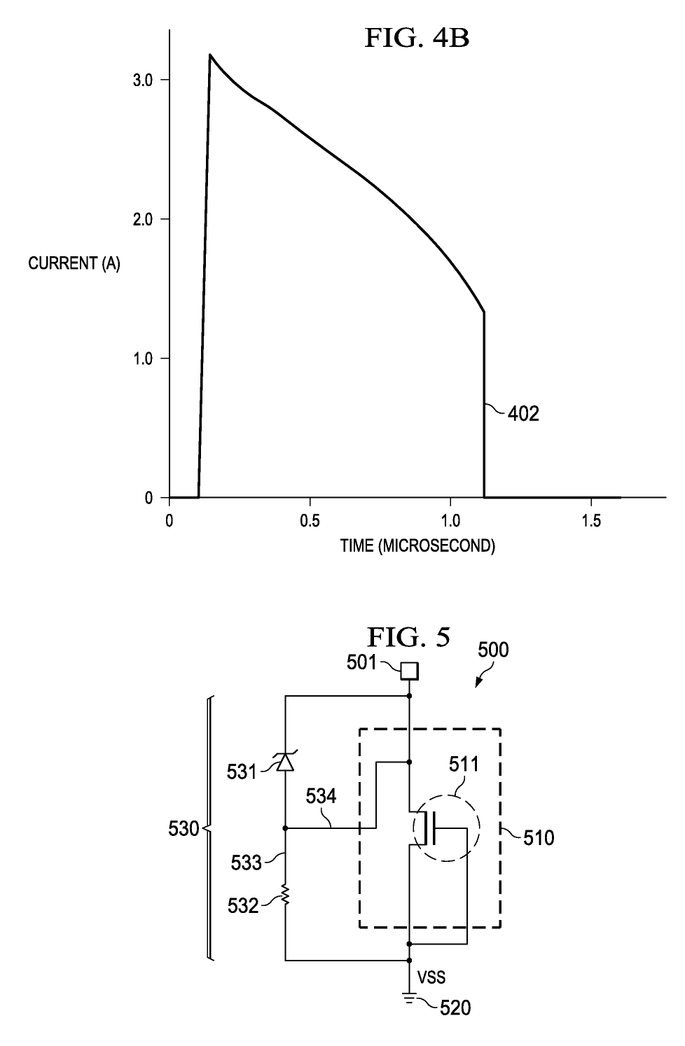

In contrast, in conventional hot plug protection using a timer set at about 3 to 5 μs, an analogous test may result in data as displayed in FIGS. 4A and 4B. In FIG. 3A, the voltage (in V) at the shut-off pin is plotted as a function of time (μs). As curve 401 shows, the voltage stays at 40 V for about 1 μs. In FIG. 3B, the corresponding current (in A) is plotted on the same time scale (μs). As curve 402 shows, the current reaches about 3 A and exhibits a slow decline; even after a time lapse of 1 μs, it still has a substantial value of about 1.4 A. By drawing an excessive amount of current, the energy which the incoming pulse is permitted to dissipate is significant (about 40 A·3 V·3·10⁻⁶ s=3.6·10⁻⁴ J).

As stated, for programmable resistors or capacitors, the threshold of the voltage sensing circuit can be adjusted. For example, the initial design may be for a hot-plug to a 40 V supply, and 1 kΩ resistors are chosen for impedances 131 and 132 in FIG. 1. If there were an application in which the same chip plugs into a 10 V supply, there would be an issue with the circuit as the resistor values needed to be changed. However, using programmable resistors or capacitors, the users would be able to adjust the voltage sensing element to allow the hot-plug feature to work for other than 40 V supply values.

In another embodiment of the invention, illustrated in FIG. 5, the voltage divider includes a non-linear element such as a Zener diode, which is characterized by a breakdown voltage V_{Zener}. In the hot plug immune circuitry 500, the shut-off pin 534 is connected to the pad-to-be-protected 501 by a Zener diode 531. Pad 501 has a pad threshold voltage V_{pad}_{_}ₜₕ. The protection circuit, designated 510, includes a MOS field effect transistor (FET) 511, which has its drain connected to pad 501 and its source, together with its gate, tied to ground potential V_{SS} 520. For protection, circuit 510 relies on the mode of a parasitic bipolar transistor (the source acts as the emitter, the drain as the collector, and the bulk semiconductor as the base) during an ESD event to provide a low impedance current path to ground; the parasitic bipolar transistor operates in the snapback regime.

Pad 501 is further connected to ground potential by a voltage divider 530, aligning in series a Zener diode 531 and a resistor 532. The Zener diode 531 is coupled to pad 501 and the resistor 532 is coupled to ground potential 520. The link 533 between the Zener diode and the resistor is connected by cross-tie p₀ (534) to the FET 511 of the protection circuit. Cross-tie 534 is operable to shut off FET 511 from pad 501 at a shut-off threshold voltage Vₚ₀_{_}ₜₕ, which is given by the following relationship:

Vₚ₀_{_}ₜₕ=V_{pad}_{_}ₜₕ−V_{Zener}.

As the equation shows, the voltage of the shut-off pin can be determined by selecting a Zener diode with a suitable breakdown voltage.

It is a technical advantage that the methodology of supplementing an ESD protection circuit with a voltage divider in order to render the protection circuit immune against hot plug events is applicable to various voltage ratings and across a wide range of technologies.

It is another technical advantage that the shut-off voltage is biased through the I/O pin and takes advantage of the existing ESD protection circuit; as a consequence, the action for turning off the protection circuitry in case of a hot plug event does not need new components or circuits; on the other hand, the ESD performance remains unchanged.

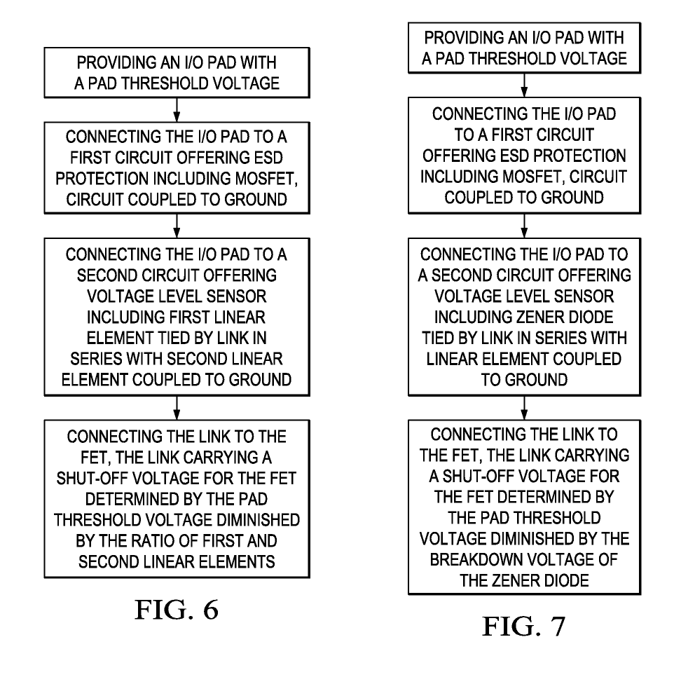

Another embodiment of the invention is a method of fabricating a hot plug immune ESD protection circuitry. A diagram of the sequence of processes of the method is illustrated in FIG. 6. The method starts in process 601 by providing an input/output (I/O) pad of an electronic system with a pad threshold voltage. In the next process 602 the I/O pad is connected to a first circuit, which offers ESD protection and includes an MOS field-effect transistor (FET); the protection circuit is coupled to ground potential.

In process 603, the I/O pad is connected to a second circuit, which is a voltage level sensor based on a voltage divider. The voltage divider includes a first electronic element tied by a link in series with a second electronic element, which in turn is coupled to ground potential. The first and the second element have linear current-voltage characteristics. Preferably, the linear electronic elements are selected from a group including impedances, resistors, capacitors, inductors, and combinations thereof.

In the next process 604, the link is cross-tied to the FET of the first circuit. The link carries a shut-off voltage for the FET; the shut-off voltage is determined by the pad threshold voltage diminished by the ratio of the first and the second electronic elements.

Yet another embodiment of the invention is another method for fabricating a hot plug immune circuitry for protecting against electrostatic discharge (ESD) events. A diagram of the sequence of processes of the method is illustrated in FIG. 7. After selecting in process 701 an input/output (I/O) pad of an electronic system with a pad threshold voltage, the I/O pad is connected in process 702 to a first circuit, which offers ESD protection and includes an MOS field-effect transistor (FET); the protection circuit is coupled to ground potential.

In the next process 703, the I/O pad is connected to a second circuit, which is a voltage level sensor based on a voltage divider. The voltage divider includes a non-linear electronic element tied by a link in series with a linear electronic element, which in turn is coupled to ground potential. The first element has a breakdown voltage. Preferably, the non-linear element is a Zener diode with a Zener breakdown voltage. The linear element is selected from a group including impedances, resistors, capacitors, inductors, and combinations thereof.

In the next process 704, the link is cross-tied to the FET of the first circuit. The link carries a shut-off voltage for the FET determined by the pad threshold voltage diminished by the breakdown voltage of the first element, preferably the breakdown voltage of the Zener diode.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the embodiments are effective in pMOS transistors as well as in nMOS transistors to create ESD protection. As another example, the semiconductor substrate material may include silicon, silicon germanium, gallium arsenide, gallium nitride, and other semiconductor materials employed in manufacturing.

As yet another example, the process of supplementing an ESD protection circuitry with a voltage divider in order to render the protection circuit immune against hot plug events can be applied to various voltage ratings and across a wide range of technologies.

It is therefore intended that the appended claims encompass any such modifications or embodiments.

I claim:

1. A hot plug immune circuitry for protecting against electrostatic discharge events, comprising:
an input/output (I/O) pad of an electronic system, the pad having a pad threshold voltage and being connected to ground potential by a first circuit and a parallel second circuit;
the first circuit including a MOS field-effect transistor (FET) doubling as a parasitic bipolar transistor;
the second circuit being a voltage level sensor formed as a voltage divider having a first electronic element tied by a link in series with a second electronic element, the first and the second element having linear current-voltage characteristics; and
the link cross-tied to the FET of the first circuit, and carrying a shut-off voltage for the FET determined by the pad threshold voltage diminished by the ratio of the first and the second electronic elements.

2. The circuitry of claim 1 wherein the linear electronic elements are selected from a group including impedances, resistors, capacitors, inductors, and combinations thereof.

3. The circuitry of claim 2 wherein the resistors or capacitors are programmable.

4. A hot plug immune circuitry for protecting against electrostatic discharge events, comprising:
an input/output (I/O) pad of an electronic system, the pad having a pad threshold voltage and being connected to ground potential by a first circuit and a parallel second circuit;
the first circuit including a MOS field-effect transistor (FET) doubling as a parasitic bipolar transistor;
the second circuit formed as a voltage level sensor comprising a non-linear electronic element coupled to the I/O pad and linked in series by a linear electronic element to ground; and
the link cross-tied to the FET of the first circuit, and carrying a shut-off voltage for the FET determined by the pad threshold voltage diminished by the breakdown voltage of the non-linear electronic element.

5. The circuit of claim 4 wherein the non-linear element is a Zener diode having a Zener breakdown voltage, and the linear element is selected from a group including impedances, resistors, capacitors, inductors, and combinations thereof.

6. A method for fabricating a hot plug immune circuitry for protecting against electrostatic discharge (ESD) events, comprising:
providing an input/output (I/O) pad of an electronic system, the pad having a pad threshold voltage;
connecting the I/O pad to a first circuit offering ESD protection including an MOS field-effect transistor (FET), the protection circuit coupled to ground potential;
connecting the I/O pad to a second circuit offering a voltage level sensor including a first electronic element tied by a link in series with a second electronic element coupled to ground potential, the first and the second element having linear current-voltage characteristics; and
connecting the link to the FET of the first circuit, the link operable to carry a shut-off voltage for the FET determined by the pad threshold voltage diminished by the ratio of the first and the second electronic elements.

7. The method of claim 6 wherein the linear electronic elements are selected from a group including impedances, resistors, capacitors, inductors, and combinations thereof.

8. The method of claim 6 wherein the resistors or capacitors are programmable.

9. A method for fabricating a hot plug immune circuitry for protecting against electrostatic discharge (ESD) events, comprising:
providing an input/output (I/O) pad of an electronic system, the pad having a pad threshold voltage;
connecting the I/O pad to a first circuit offering ESD protection including an MOS field-effect transistor (FET), the protection circuit coupled to ground potential;
connecting the I/O pad to a second circuit offering a voltage level sensor including a non-linear electronic element tied by a link in series with a linear electronic element coupled to ground potential, the first element having a breakdown voltage; and
connecting the link to the FET of the first circuit, the link operable to carry a shut-off voltage for the FET determined by the pad threshold voltage diminished by the breakdown voltage of the first element.

10. The method of claim 9 wherein the non-linear element is a Zener diode having a Zener breakdown voltage, and the linear element is selected from a group including impedances, resistors, capacitors, inductors, and combinations thereof.
